(19) United States
(12) Patent Application Publication
(10) Pub. No.: US 2005/0233252 A1
(43) Pub. Date: Oct. 20, 2005

(54) Stereoflexography

(76) Inventor: Eudes Dantas, Rio de Janeiro (BR)

Correspondence Address: PEARNE & GORDON LLP, 1801 EAST 9TH STREET, SUITE 1200, CLEVELAND, OH, 44114-3108, US

(21) Appl. No.: 10/525,628

(22) PCT Filed: Aug. 22, 2003
(86) PCT No.: PCT/BR03/00119

§ 371 Date: Feb. 25, 2005

(30) Foreign Application Priority Data
Aug. 29, 2002 (BR) PI02034280
Dec. 17, 2002 (BR) C102034280

(51) Int. Cl. G03F 7/00

(52) U.S. Cl. 430/306; 101/401.1

(57) ABSTRACT

Improvement to the photopolymers catalysis in printing plates for the flexographic and of stamp sectors (FIG. 1), by exposing the photopolymer plate (1), only, by the bottom face (2), to two different and simultaneous levels of radiation; a lower, to catalyze the base of the relief (8) and a maximum, to catalyze the printing relief (10), emitted by radiation device (5, 6), polarized by filter (7), which uses a negative film whose black area is replaced by halftone (3), thereby originating the low radiation level, and keeping its transparent area (4), thereby originating the maximum radiation level, thickening the base of the dot (9) and sharpening the top of the dot (10), thereby eliminating the ‘dot droop’ and the ‘dot gain’, respectively; or which uses optic semiconductors, which digitally modulate the radiation in a fixed way (FIG. 2) for the stamp sector, with DMD or LCD (1), and in a mobile way (FIG. 3), with DMD (1), for the flexographic sector.

This patent seeks to protect the catalysis process (cure) of plates for graphic printing formed by photopolymer, in either liquid or solid state, for the stamps and flexographic sectors, respectively.

The flexographic sector's origins date back to the ancient woodcuts, texts and images carving in wood plates, used in the first stamps for graphic printing. Today, flexography differs from stamps, only, in the higher resolution of its printing plates, which is necessary to allow us to define its screen printing (‘CMYK’ system), and is similar in the remaining of the making, including the generation of printing relief third dimension, which is not necessary in two-dimensional printing plates used in the off-set sector.

Now, an analogical flexographic plate, made up by solid photopolymer, anchored in a transparent laminated plastic, is processed on both sides, separately, in a space procedure, for exposure to a radiation that ranges from ultraviolet (UV) to the visible light. The entire area of the bottom face (back exposure), anchored in the transparent laminate is exposed to the radiation, thereby generating a base whose thickness is proportional to the exposition time. The upper face (main exposure), designed for graphic printing, are exposed, only, in which texts and images (screen printing CMYK), in a ‘black and white’ negative film, allow a passage, thereby generating a relief on that base, after the washing to remove the non-catalyzed portion. In the digital process, the negative film is replaced by a black pellicle, which is sensitive to the infrared laser, adhered to the upper face, thereby originating a flexographic digital plate.

The ‘Stereoflexography’ is an improvement in the photopolymer plates making process, either in liquid or solid state, processed by the action of two-dimensional analogical or digital emission devices, which emit radiations ranging from the visible to the invisible spectrum. It is characterized by the ‘main exposure’ and ‘back exposure’ of the photopolymer plate to the radiation, only, to the bottom face (2), thereby catalyzing the formation of both the relief base (8) and the printing relief (10), simultaneously, by the action of two different radiation levels: a low, to generate the relief base (8) and a maximum, to generate the printing relief (10). The neologism ‘Stereoflexography’ is the most appropriate for this new process because it generates the third dimension in the photopolymer plate, resulting from adding the height of the relief base (8) to the height of the printing relief (10), thereby generating the relief that is necessary to the graphical printing of texts and image on a flat and flexible substance, starting from any two-dimensional (negative film, LCD or DMD) radiation emission device.

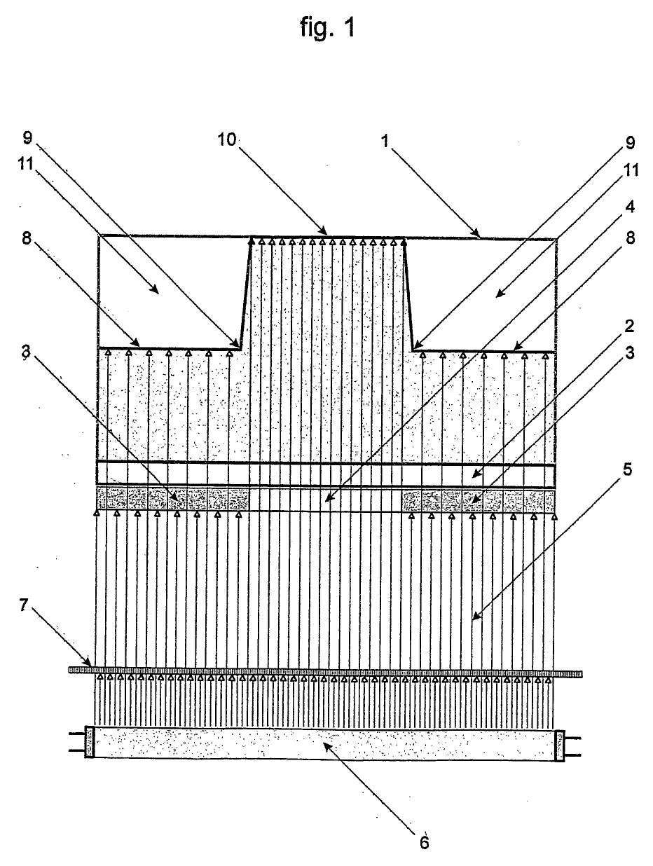

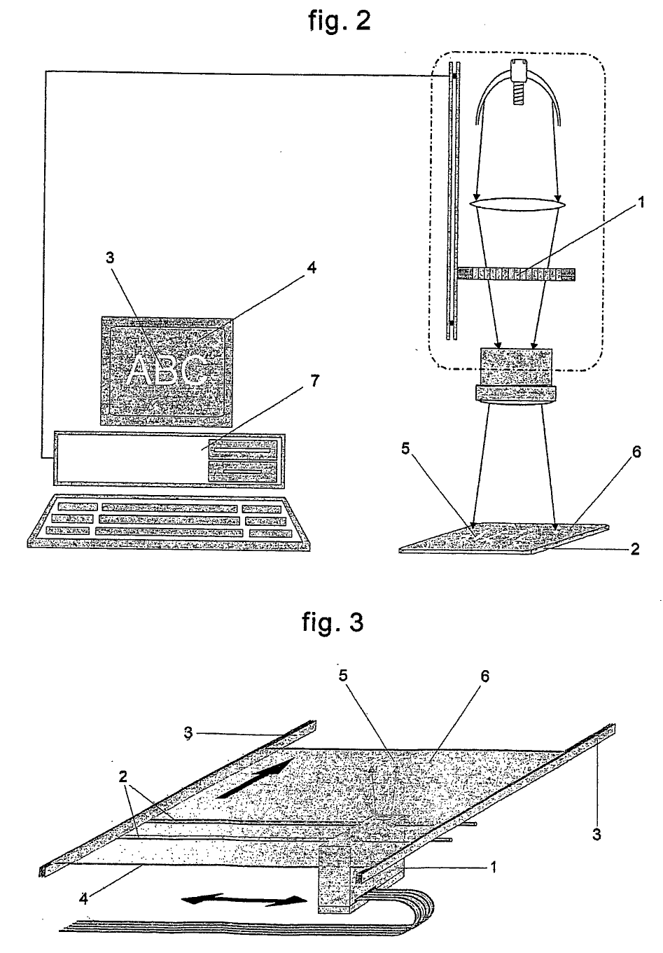

To facilitate the understanding of this process, see FIG. 1, shows an analogical two-dimensional emission device and a flexographic plate, formed by a 2 mm thick photopolymer, shown in a 30-time enlarged cross-section, in which both the upper face (1) and the bottom face (2) made up by a transparent laminated plastic. The emission device, in this case, is formed by a black and white negative film, In which the black area was replaced by a pre-established percentile (halftone) of grey (3), and having the transparent area (4) placed against the bottom face (2); and a flat UV light source (6), emitting its radiation (5), polarized by the filter (7). The black area of the negative film, replaced by the percentile of grey (3), will have the function of allowing the low radiation level to pass through, thereby creating the relief base (8); whilst the white area (transparent) (4) of the negative film, will have the function of allowing a passage for the maximum radiation level, thereby creating the dot relief (10), after the washing to remove the non-catalyzed portions (11). By establishing one single radiation exposure time, as necessary to form the printing relief (10), the percentile of grey will be altered, which will allow the, exact, amount of radiation to pass through to form the thickness that is adequate for the relief base (8), which will in turn be catalyzed (cured), simultaneously, with the printing relief.

1-6. (canceled)

7. A stereoflexographic process, wherein a liquid or solid photopolymer plate is cured through the bottom face only with two different and simultaneous levels of radiation,
a lower level, suitable to catalyze the relief base generation, replacing back exposure by percentile of gray (halftone); and
a maximum level, suitable to catalyze the printing relief generation, replacing main exposure, creating the high relief third dimension, which is necessary for those photopolymer plates destined for the flexographic and stamp sectors by applying an analogical exposure equipment, based on photoliths, negative films and lamps or processing digitally in emission devices, modulating the radiation in optic semiconductors, replacing photoliths and negative films by LCD (Liquid Crystal Diode) or DMD (Digital Mirror Device).

8. Process according to claim 7, characterized by speeding up the process and reducing production time for prosecuting only by the bottom face of the photopolymer plate.

9. Process according to claim 7, characterized by eliminating the dot gain usually occurring in flexographic plates, which is caused by the effects of the refraction and persistence of radiation inside the photopolymer, thickening the top of the dot when the expositions to radiation is done by the upper face (main exposure) arid by the bottom face (back exposure), thereby damaging the resolution in said plates, by applying the emission, only, on the bottom face, the effects of refraction and persistence of radiation are inverted, sharpening the top of the dot, and consequently improving resolution in said plates.

10. Process according to claim 7, characterized by eliminating the dot droop usually occurring in flexographic plates, which is caused by the effects of the refraction and persistence of radiation inside the photopolymer, sharpening the base of the dot and thickening the top of the dot, when the expositions to radiation is done by the upper face (main exposure) and by the bottom face (back exposure), thereby weakening plate structure and reducing the durability of these plates, by applying the emission, only, on the bottom face, the effects of refraction and persistence of radiation are inverted, thickening the base of the dot and sharpening the top of the dot, thereby reinforcing plate structure and increasing the durability of these plates.

11. Process according to claim 7, wherein stereoflexography solves problems as neatness which is caused by processing by both the upper face (main exposure) and the bottom face (back exposure), it will allow the development of new light and compact pieces of equipment to manufacture photopolymer plates in the stamp sector, characterized by the use of a fixed device which process digitally, modulating the radiation in optic semiconductors, type LCD (Liquid Crystal Diode) or DMD (Digital Mirror Device), necessary to catalyze the photopolymer plate, thereby transferring text and image files, to generate of the printing relief, simultaneously, with the percentile of gray (halftone) to generate the relief base, directly from the computer, discarding, in these two improvements, the use of negative films and their supplies.

12. Process according to claim 7, wherein the elimination of dot gain and dot droop provided by stereoflexography will guarantee great neatness and longer lifetime to the flexographic plates processed in the new equipment, which is characterized by a mobile device, in shaft X and shaft Y, parallel to the photopolymer plate, processing digitally, modulating the radiation in optic semiconductors, type LCD (Liquid Crystal Diode) or DMD (Digital Mirror Device), necessary to catalyze the photopolymer plate, thereby transferring screen printing (CMYK system) of the texts and images files, to generate of the printing relief, simultaneously, with the percentile of gray (halftone) to generate the relief base, directly from the computer, discarding, in these two improvements, the use of photoliths and negative films.
